(19) United States
(12) Patent Application Publication
(10) Pub. No.: US 2007/0018278 A1
(43) Pub. Date: Jan. 25, 2007

(54) Semiconductor memory device

(76) Inventors: Michael Kund, Tuntenhausen (DE); Josef Willer, Riemerling (DE)

Correspondence Address: SLATER & MATSIL LLP, 17950 PRESTON ROAD, SUITE 1000, DALLAS, TX, 75252, US

(21) Appl. No.: 11/189,098

(22) Filed: Jul. 25, 2005

(51) Int. Cl. H01L 29/00

(52) U.S. Cl. 257/510

(57) ABSTRACT

The channel regions (T) of the memory cells are directed transversly to the word lines (2), which are arranged parallel at a distance from one another. Local interconnects (6) connect the source/drain regions of the memory cell transistors to bit lines running across the word lines and are connected to local interconnects in every next but one interspace between neighboring word lines. Every local interconnect is connected to only one source/drain region, which is enabled by enlarged shallow trench isolations (7) between the active areas. This memory cell array allows an individual programming and erasing of every single cell and can be integrated with a flash memory array comprising local interconnects and upper bit lines and is intended for file storage.

### TECHNICAL FIELD

The present invention relates to flash memories, more specifically to charge-trapping storage devices, with the goal of highest endurance and smallest possible bit size.

### BACKGROUND

Flash memories are usually arranged in an architecture in which erasure takes place for blocks of memory cells. However, there are applications of memory products that require fast random access including individual programming and erasing of single memory cells.

In PCT Patent Application WO 2004/053982, which is incorporated herein by reference, a memory cell array is described that comprises word lines and bit lines that are arranged above a main surface of a semiconductor substrate. The direction of the channels of the transistor structures forming the memory cells is transverse to the direction of the word lines. The appertaining source/drain regions are electrically connected by local interconnects which are arranged in the gaps between neighboring word lines. The bit lines are connected to the local interconnects according to a pattern that is required by the memory array architecture.

U.S. Patent Application Publication No. 2005/0045935, which is incorporated herein by reference, describes a similar arrangement comprising a memory cell array with local interconnects between the source/drain regions and the bit lines. This array is divided into slices, which are obtained by an interruption of the periodical sequence of memory cells along the word lines. This can be achieved either by a substitution of the transistor structures by dielectric material or by interrupting the sequence of local interconnects or bit line contacts in regions along the bit lines that are located between two adjacent slices.

Memory devices with charge-trapping layers, especially SONOS memory cells comprising oxide-nitride-oxide layer sequences as storage medium, are usually programmed by channel hot electron injection. U.S. Pat. Nos. 5,768,192 and 6,011,725, which are each incorporated herein by reference, disclose charge-trapping memory cells of a special type of so-called called NROM cells, which can be used to store bits of information both at the source and at the drain below the respective gate edges. The programmed cell is read in reverse mode to achieve a sufficient two-bit separation. Erasure is performed by hot hole injection.

### SUMMARY OF THE INVENTION

In one aspect, this invention aims at the integration of flash memory cells that are provided for a direct-execution-in-place capability into a file storage device.

In a further aspect, this invention minimizes read disturb while at the same time providing state of the art code flash data retention as well as cyclability.

In still a further aspect, this invention enables the integration of memory cells that are provided for a direct random access, including individual erasability, into flash memory arrays comprising a virtual-ground architecture with local interconnects between source/drain regions and bit lines that are arranged above the word lines.

The semiconductor memory device according to a preferred embodiment comprises a substrate having a main surface and a plurality of shallow trench isolations being arranged along a first direction in a region of the main surface. A plurality of electrically conductive word lines are arranged along a second direction transverse to the first direction, and are isolated from the substrate at least partially by a trapping dielectric. Source/drain regions are arranged in the substrate adjacent to the word lines and are limited in the second direction by pairs of shallow trench isolations. A plurality of electrically conductive local interconnects are arranged above the source/drain regions. A plurality of electrically conductive bit lines are arranged along the first direction above the local interconnects. Each of the interconnects connect one of the source/drain regions to one of the bit lines in such a manner that the source/drain regions that are subsequent in the first direction between the same shallow trench isolations are in their sequence connected alternatingly to one of two neighboring bit lines.

In a further embodiment, this invention provides a semiconductor memory device, in which the shallow trench isolations are limited in the second direction by boundaries. The boundaries have a distance from one another in the second direction, which is the same at every location along the boundaries. The boundaries are curved or broken in such a manner that a longitudinal direction of the shallow trench isolations, which is defined by a tangent to the boundaries, makes a first angle with the first direction in middle positions beneath every next but one of the word lines and a second angle with the first direction in middle positions beneath the other ones of the word lines. The first and second angles are opposite to one another.

The memory cell array can be integrated with a further array, which comprises a plurality of further shallow trench isolations formed in a further region of the main surface. The further shallow trench isolations are arranged parallel to one another and at a distance from one another. A plurality of electrically conductive further word lines are arranged transversely to the further shallow trench isolations and are isolated from the substrate at least partially by a trapping dielectric. Further source/drain regions are arranged in the substrate adjacent to the further word lines. A plurality of electrically conductive further local interconnects are arranged above the further source/drain regions and the further shallow trench isolations. A plurality of electrically conductive further bit lines are arranged along the further shallow trench isolations above the further interconnects. The further source/drain regions, the further word lines, the further bit lines and the trapping dielectric form an array of memory cells. The further interconnects are arranged between the further word lines in such a fashion that in a first quadruple of memory cells comprising a first memory cell, a second memory cell that is adjacent to the first memory cell in a direction of the further word lines, and a third memory cell and a fourth memory cell that are adjacent to the first and second memory cells, respectively, in a direction of the further bit lines, and further comprising a first further source/drain region of the first memory cell, a first further source/drain region of the second memory cell, a first further source/drain region of the third memory cell, and a first further source/drain region of the fourth memory cell, the first further source/drain regions are electrically connected by a first one of the further interconnects and, the memory cells of the first quadruple forming first memory cells of a second, third, fourth, and fifth quadruple of memory cells arranged like the first quadruple, a second further source/drain region of each of the memory cells of the first quadruple is electrically connected to first further source/drain regions of a second, third, and fourth memory cell of the respective second, third, fourth or fifth quadruple of memory cells by a second, third, fourth, and fifth one, respectively, of the further interconnects.

These and other features and advantages of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-section of a plan view onto a flash memory array in a virtual-ground architecture comprising local interconnects to upper bit lines;

FIG. 2 shows a plan view onto the device according to FIG. 1, including the arrangement of the bit lines;

FIG. 3 shows a modification of the arrangement according to FIG. 1 according to the present invention;

FIG. 4 shows a diagram including the bit lines, showing the connection of the word lines and bit lines to the memory cells in a schematic way;

FIG. 5 shows a cross-section of the device transverse to the bit lines along one of the word lines;

FIG. 6 shows a cross-section of the device coplanar to the cross-section of FIG. 5 in the area between two word lines;

FIG. 7 shows the circuit diagram of the connections of the memory cell array to the bit lines and word lines, according to the schematic view shown in FIG. 4; and

FIG. 8 shows a plan view according to FIG. 4 of an alternative embodiment.

The following list of reference symbols can be used in conjunction with the figures: 1 shallow trench isolation 2 word line 3 lateral word line insulation 4 bit line 5 bit line contact 6 local interconnect 7 enlarged shallow trench isolation 8 gate dielectric 9 first word line layer 10 second word line layer 11 substrate 12 well 13 cover layer 14 bit line wire T channel region

### DETAILED DESCRIPTION OF ILLUSTRATIVE EMBODIMENTS

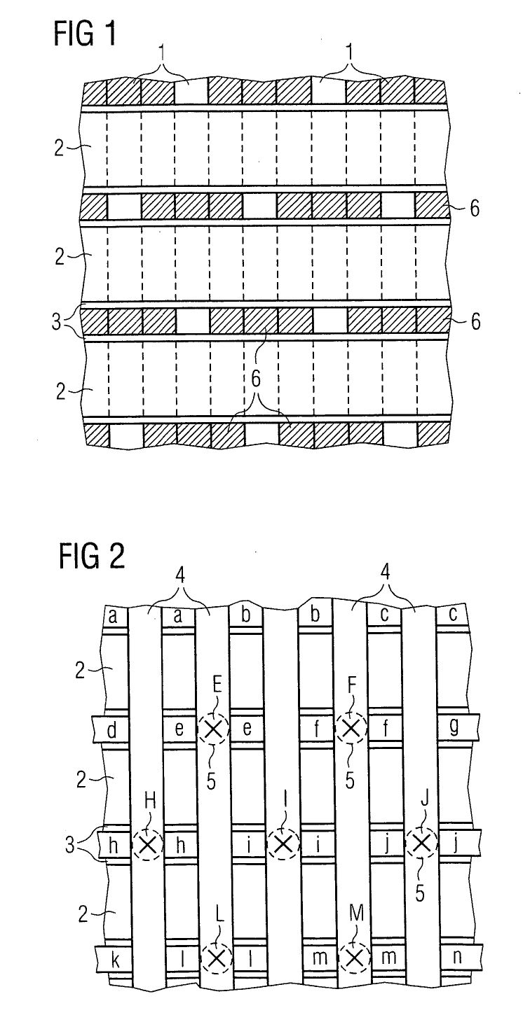

FIG. 1 shows a plan view of a scheme of a semiconductor memory according to the cited prior art, in which the channel regions are directed transversely with respect to the relevant word line and the bit lines are arranged on top of the word lines and electrically insulated from the word lines. Shallow trench isolations 1 represent a multiplicity of isolation trenches that are arranged parallel at a distance from one another and are filled with dielectric material, preferably with an oxide of the semiconductor material. The channel regions of the memory transistors run parallel to the isolation trenches underneath the word lines 2 and are arranged between two adjacent shallow trench isolations 1. Thus, the word lines are transverse to the longitudinal extension of the channel regions. Electrically conductive interconnects 6 are present in interspaces between the word lines 2 and are electrically insulated from the word lines by lateral word line insulations 3 and from one another by a dielectric material that is filled into the interspaces. The local interconnects are connected to the bit lines, which are arranged above the word lines and electrically insulated from the word lines.

The source/drain regions of the memory transistors are in each case present in a manner laterally adjoining the word lines. Neighboring source/drain regions are electrically conductively connected to one another in the regions that are highlighted by the hatchings in FIG. 1, a short section of one of the shallow trench isolations being bridged in each case.

In accordance with a consecutive numbering of the memory transistors along a respective word line, the interconnects 6 electrically conductively connect, on one side of the word line, in each case a source/drain region of an even-numbered memory transistor to a source/drain region of the subsequent odd-numbered memory transistor in the numbering and, on the opposite side of this word line, in each case a source/drain region of an odd-numbered memory transistor to a source/drain region of the subsequent even-numbered memory transistor in the numbering.

Figureure 2 illustrates a plan view of this arrangement including the bit lines 4 applied above the word lines 2 parallel to the shallow trench isolations. The local interconnects 6 that are present in the regions that correspond to the hatched areas of FIG. 1 are each designated in FIG. 2 by one lower-case letter. The interconnects 6 are contact-connected by the bit lines 4. The bit line contacts 5 are depicted by broken lines as concealed contours in FIG. 2 and identified by a cross. Furthermore, the bit line contacts 5 are in each case designated by the upper-case letter, which corresponds to the lower-case letter of the appertaining interconnect 6.

It can be seen in FIG. 2 that the bit lines 4 are in each case electrically contact-connected to interconnects 6 that are arranged successively in the direction of the bit lines in next but one interspaces between the word lines 2. The interconnects 6 bridge a shallow trench isolation 1 and each connect one source/drain region to a subsequent source/drain region of the same interspace between the adjacent word lines. They are electrically insulated from one another and, therefore, formed in sections and isolated from one another by dielectric material.

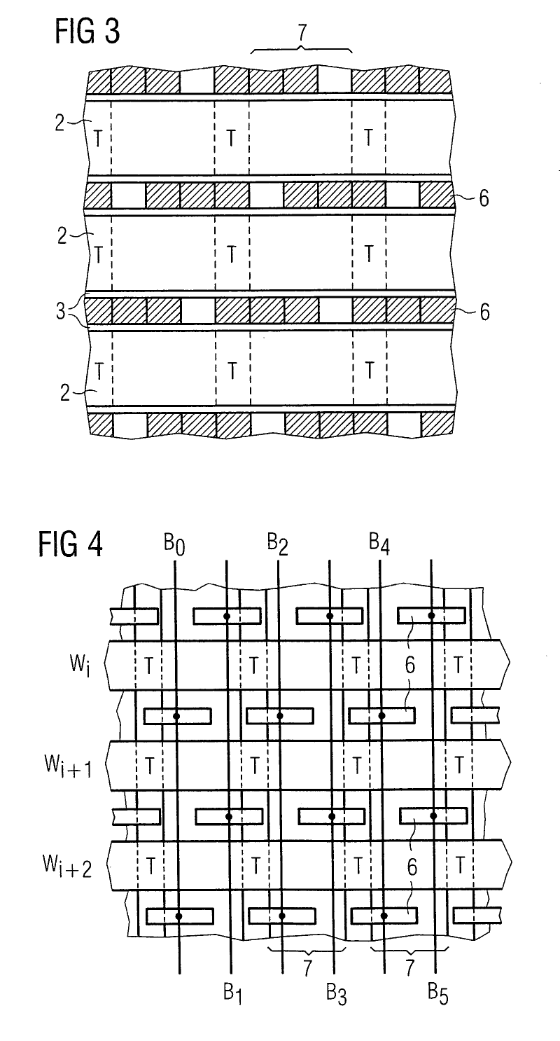

FIG. 3 shows a plan view of a cross-section of the inventive device with the location of the transistor structures and the word lines. The arrangement of the word lines 2 with the lateral word line insulations 3 and the local interconnects 6, which are highlighted by the hatchings, is similar to the known memory cell array according to FIG. 1. However, the spacing of the active areas is considerably larger in the inventive array so that there are enlarged shallow trench isolations 7 between the active areas. This embodiment is especially advantageous, because it can be obtained by just leaving out every second active area in a periodic sequence. Thus, it is possible to integrate the memory cell array according to FIG. 1 and the memory cell array according to FIG. 3 in the same semiconductor device without essentially changing the bit line pitch. If the bit lines are arranged and contacted on the local interconnects according to the arrangement of FIG. 2, the enlarged shallow trench isolations 7 render electric connections of the bit lines via the local interconnects to only one source/drain region of a memory cell transistor that is addressed by the corresponding word line. This can be seen from the schematic diagram of FIG. 4.

FIG. 4 shows the view of FIG. 3 with the word lines 2 designated by Wᵢ, Wᵢ₊₁, Wᵢ₊₂. The local interconnects 6 are drawn in FIG. 4 clearly detached from the word lines in order to show the electric insulation between the local interconnects and the word lines. The active areas between the shallow trench isolations comprise the transistor structures; their channels are located underneath the word lines and are marked with the letter T. The bit lines that run transversely across the word lines are only indicated by straight lines that do not cover the underlying structure in the drawing of FIG. 4. Actually, the bit lines are formed as conductive stripes above the word lines and electrically insulated from the word lines. As can be seen from FIG. 4, the even-numbered bit lines B₀, B₂, and B₄ are connected to local interconnects 6 that are located in every next but one interspace between neighboring word lines. The odd-numbered bit lines B₁, B₃, and B₅ are connected to the local interconnects that are located in the other interspaces between the word lines. As every local interconnect makes a contact with only one of the source/drain regions, and since the source/drain regions that are located in the same column are alternatingly connected to the two neighboring bit lines, two neighboring bit lines are connected to one and only one memory cell of a selected row of this array. Therefore, by addressing one word line and two neighboring bit lines, each cell of this array can be addressed individually and unambiguously.

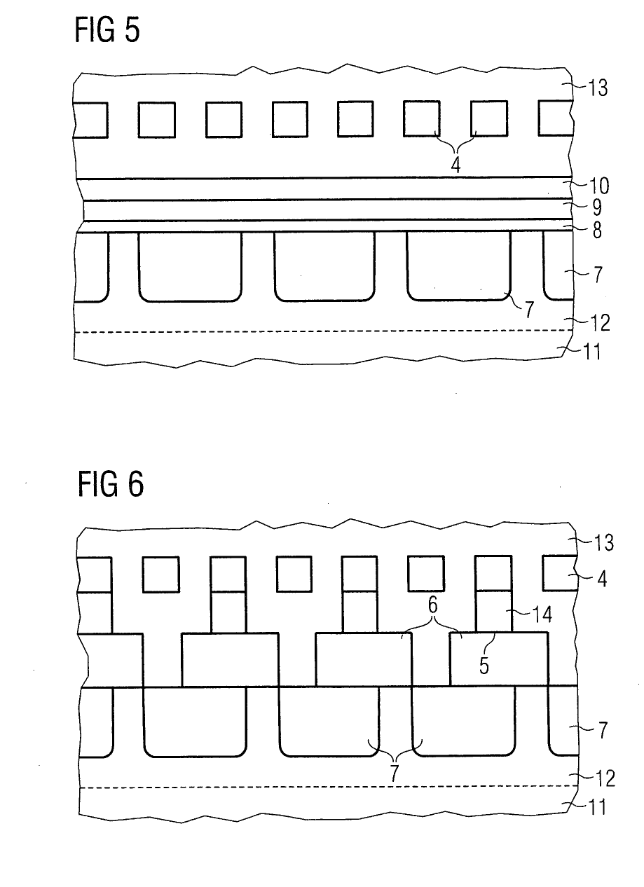

The cross-section through one of the word lines of this device is shown in FIG. 5. The semiconductor substrate 11 is provided with a doped well 12 forming the basic doping of the channel regions of the memory cells. Enlarged shallow trench isolations 7 are arranged in this well 12 and are formed relatively broad as compared to the described prior art. The trenches are filled with dielectric material, for example an oxide of the semiconductor material. A gate dielectric 8, which may comprise a layer sequence of dielectric materials including a dielectric material that is suitable for charge-trapping, is applied on the semiconductor surface. The word line is preferably formed of at least a first word line layer 9, for example electrically conductively doped polysilicon, and a second word line layer 10 of metal or metal silicide, which is provided to reduce the track resistance. A cover layer 13 of electrically insulating material covers the word line stacks and insulates the bit lines 4 electrically from the word lines.

FIG. 6 shows another cross-section of this embodiment between two word lines and coplanar to the cross-section of FIG. 5. A comparison of FIG. 5 and FIG. 6 shows that the shallow trench isolations run in strip form parallel to one another with essentially maintaining the same cross-section. Between the word lines, the local interconnects 6 are arranged so as to form sections that are electrically insulated from one another. The local interconnects are partly applied onto the semiconductor material of the well 12 and partly on the enlarged shallow trench isolations 7. The bit lines 4 are alternatingly connected to the local interconnects 6 by bit line vias 14. Every second bit line is connected to one of the local interconnects 6 in the represented interspace between the two neighboring word lines. The other bit lines are here only passing; they are connected to the local interconnects of the next interspaces between the word lines that follow in front of and behind the drawing plane.

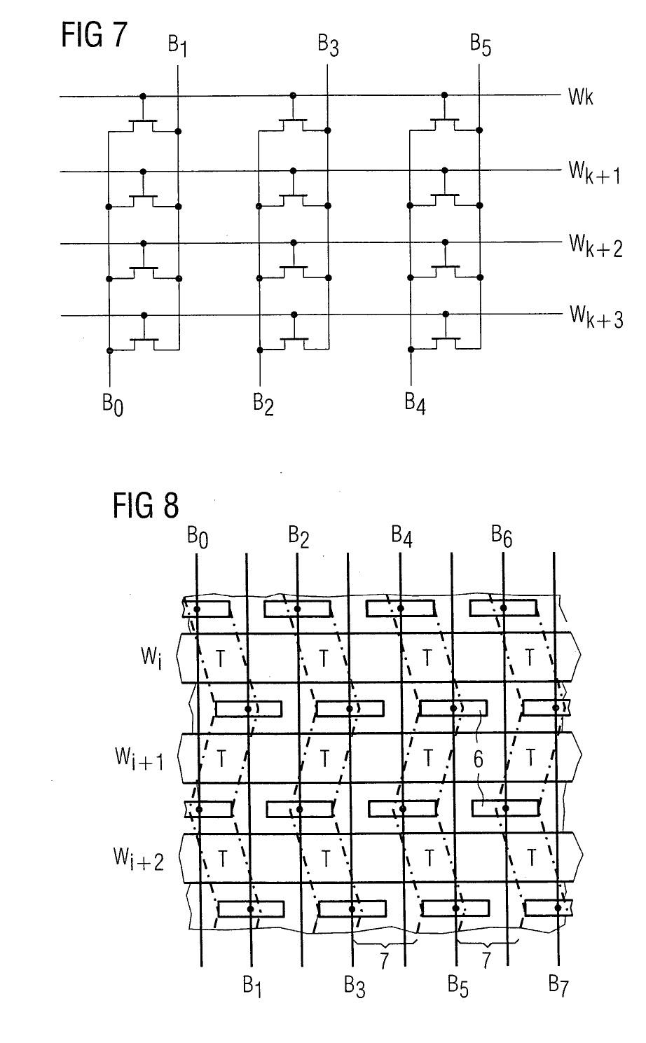

FIG. 7 shows the circuit diagram of the embodiment according to FIGS. 3 to 6. Every cell transistor is switched between two adjacent bit lines and can be addressed by one of the word lines. If the word line Wₖ₊₁ is selected, for example, the transistors of the second row of FIG. 7 can be addressed by pairs of bit lines B₀ and B₁, B₂ and B₃, and B₄ and B₅, respectively. This means that the columns of memory cells are electrically separated from one another and this memory cell array is fully flexible, favorable to individual addressing of single memory cells. This array architecture results in a parallel arrangement of cells, forming a NOR architecture.

FIG. 8 shows another embodiment, which comprises active areas that are formed as curved or broken strips, changing direction between every two word lines. In this way, the width of the active areas can be enlarged, and a higher read current with improved access time can be achieved. The bit lines are again preferably formed as rectilinear strips above the local interconnects. The electric connections are similar to the preceding embodiment, and the circuit diagram of FIG. 7 also holds for the embodiment of FIG. 8. This semiconductor memory device offers an improved memory performance due to an array architecture that can easily be integrated with a virtual-ground array comprising bit lines that are connected to the source/drain regions by local interconnects. This device provides a larger programming window of more than 4 V for high-endurance code storage. As there are no shared address lines, the disturb of unselected cells is minimal, and the drain voltage is reduced to values of less than 1 V. If the memory cells are realized as charge-trapping memory cells, programming can be performed by channel hot electrons (CHE) and erasing by hot-hole injection.

What is claimed is:

1. A semiconductor memory device comprising:
a semiconductor body having a main surface and a plurality of shallow trench isolations arranged along a first direction in a region of said main surface;
a plurality of electrically conductive word lines arranged along a second direction transverse to said first direction, isolated from the semiconductor body at least partially by a trapping dielectric;
source/drain regions arranged in said semiconductor body adjacent to said word lines and being limited in said second direction by pairs of said shallow trench isolations;
a plurality of electrically conductive local interconnects arranged above said source/drain regions;
a plurality of electrically conductive bit lines arranged along said first direction above said interconnects; and
wherein each of said interconnects connects one of said source/drain regions to one of said bit lines in such a manner that the source/drain regions that are subsequent in said first direction between the same shallow trench isolations are in their sequence connected alternatingly to one of two neighboring bit lines.

2. The semiconductor memory device according to claim 1, wherein said shallow trench isolations have a first dimension in said second direction and said source/drain regions having a second dimension in said second direction, said first dimension being larger than said second dimension.

3. The semiconductor memory device according to claim 2, wherein said first dimension is at least three times as large as said second dimension.

4. The semiconductor memory device according to claim 1, wherein:
said shallow trench isolations is limited in said second direction by boundaries;
said boundaries have a distance from one another in said second direction, said distance being the same at every location along the boundaries;
said boundaries being curved or broken in such a manner that a longitudinal direction of said shallow trench isolations, which is defined by a tangent to said boundaries, makes a first angle with said first direction in middle positions beneath every next but one of said word lines and a second angle with said first direction in middle positions beneath the other ones of said word lines; and
said first and second angles being opposite to one another.

5. The semiconductor memory device according to claim 4, wherein said boundaries are rectilinear in sections between said interconnects.

6. The semiconductor memory device according to claim 4, wherein every two neighboring ones of said boundaries are arranged at the same distance from one another.

7. The semiconductor memory device according to claim 1, wherein every two neighboring ones of said bit lines are arranged at the same distance from one another.

8. The semiconductor memory device according to claim 1, wherein said interconnects are arranged partly on said source/drain regions and partly on said shallow trench isolations.

9. The semiconductor memory device according to claim 1, further comprising:
a plurality of further shallow trench isolations formed in a further region of said main surface, said further shallow trench isolations being arranged parallel to one another and at a distance from one another;
a plurality of electrically conductive further word lines being arranged transversely to said further shallow trench isolations and isolated from the substrate at least partially by a trapping dielectric;
further source/drain regions arranged in said substrate adjacent to said further word lines;
a plurality of electrically conductive further local interconnects arranged above said further source/drain regions and said further shallow trench isolations;
a plurality of electrically conductive further bit lines arranged along said further shallow trench isolations above said further interconnects;
said further source/drain regions, said further word lines, said further bit lines and said trapping dielectric forming an array of memory cells, wherein
the further interconnects are arranged between the further word lines in such a fashion that in a first quadruple of memory cells comprising a first memory cell, a second memory cell that is adjacent to the first memory cell in a direction of the further word lines, and a third memory cell and a fourth memory cell that are adjacent to the first and second memory cells, respectively, in a direction of the further bit lines, and further comprising a first further source/drain region of the first memory cell, a first further source/drain region of the second memory cell, a first further source/drain region of the third memory cell, and a first further source/drain region of the fourth memory cell;
the first further source/drain regions are electrically connected by a first one of the further interconnects; and
the memory cells of the first quadruple forming first memory cells of a second, third, fourth, and fifth quadruple of memory cells arranged like the first quadruple; and
a second further source/drain region of each of the memory cells of the first quadruple is electrically connected to first further source/drain regions of a second, third, and fourth memory cell of the respective second, third, fourth or fifth quadruple of memory cells by a second, third, fourth, and fifth one, respectively, of the further interconnects.

10. The semiconductor memory device according to claim 1, further comprising:
a plurality of further shallow trench isolations formed in a further region of said main surface;
said further shallow trench isolations arranged parallel to one another and at a distance from one another;
a plurality of electrically conductive further word lines arranged transversely to said further shallow trench isolations and isolated from the substrate at least partially by a trapping dielectric;
further source/drain regions arranged in said substrate adjacent to said further word lines;
a plurality of electrically conductive further local interconnects arranged above said further source/drain regions and said further shallow trench isolations;
a plurality of electrically conductive further bit lines being arranged along said further shallow trench isolations above said further interconnects; and
said further source/drain regions, said further word lines, said further bit lines and said trapping dielectric forming an array of memory cells, wherein:
said further interconnects are arranged in interspaces between said further word lines in such a fashion that, in accordance with a consecutive numbering of the memory cells in a direction along a respective further word line, wherein:
on one side of the further word line, the further interconnects connect a further source/drain region of an even-numbered memory cell to a further source/drain region of the subsequent odd-numbered memory cell in said direction; and
on the opposite side of this further word line, the further interconnects connect a further source/drain region of an odd-numbered memory cell to a further source/drain region of the subsequent even-numbered memory cell in said direction; and
said further bit lines are connected to said further interconnects that are arranged along the relevant further bit line in next but one interspaces between the further word lines.

11. The semiconductor memory device according to claim 1, wherein the semiconductor body comprises a substrate.
